(19) United States
(12) Patent Application Publication
(10) Pub. No.: US 2024/0376586 A1
(43) Pub. Date: Nov. 14, 2024

(54) MASK ASSEMBLY MANUFACTURING DEVICE AND MASK ASSEMBLY MANUFACTURING METHOD USING THE SAME

(71) Applicant: Samsung Display Co., LTD., Yongin-si (KR)

(72) Inventors: SUNGHO PARK, Yongin-si (KR); KYONGHO HONG, Yongin-si (KR)

(21) Appl. No.: 18/643,553

(22) Filed: Apr. 23, 2024

(30) Foreign Application Priority Data
May 12, 2023 (KR) 10-2023-0061614

(51) Int. Cl. C23C 14/04; H10K 71/16

(52) U.S. Cl. CPC C23C 14/042; H10K 71/166

(57) ABSTRACT

A mask assembly manufacturing device includes: a support part including a first support part and a second support part; a stage disposed on the second support part; support units configured to support the mask frame; and first guide units configured to overlap corner parts of the mask frame, where each of the first guide units includes: a first base part; a first cover part having a first opening defined therein; a first tilting part of which one portion is disposed inside the first cover part and another portion protrudes from the first cover part to an outside through the first opening; a first guide part connected to the first base part and the first tilting part; and a first elastic part connected to the first base part and the first tilting part.

This application claims priority to Korean Patent Application No. 10-2023-0061614, filed on May 12, 2023, and all the benefits accruing therefrom under 35 U.S.C. § 119, the content of which in its entirety is herein incorporated by reference.

### BACKGROUND

The present disclosure herein relates to a mask assembly manufacturing device and a mask assembly manufacturing method using the same.

Typically, unlike a liquid crystal display device, an organic light emitting diode display (“OLED”) having excellent luminance characteristics and viewing angle characteristics and not requiring a separate light source is attracting attention as a next generation flat display device. Since not requiring a separate light source, the OLED may be manufactured in a lightweight and thin type. In addition, the OLED has the characteristics of low power consumption, high luminance, high reaction speed or the like.

The OLED includes a plurality of light emitting elements, each of which including an anode, a light emitting layer, and a cathode. Holes and electrons from the anode and cathode are injected into the light emitting element to provide excitons, and while the excitons are transitioned to the ground state, the light emitting element emits light. During manufacturing of the light emitting elements, a mask is disposed on a substrate and an organic material for providing the light emitting layers are provided to the substrate through openings of the mask.

The mask may include a mask frame having a frame opening defined therein and a frame shape, and include sub-masks on the mask frame. Openings through which the organic material penetrates may be defined in each of the sub-masks. During manufacturing of the mask, the mask frame may be supported by a support structure, and the sub-masks may be connected to the mask frame. Therefore, the support structure is required to more easily support the mask frame.

### SUMMARY

The present disclosure provides a mask stage which may more easily support a mask frame and a mask manufacturing device including the same.

An embodiment of the invention provides a mask assembly manufacturing device including: a support part including a first support part including a front surface and a rear surface opposing to each other and a second support part inclined at a certain inclination with respect to a direction vertical to the front surface; a stage disposed on the second support part to correspond to the inclination and on which a mask frame is cradled; support units disposed at a lower portion of the stage and configured to support the mask frame; and first guide units configured to be disposed between the stage and the mask frame and overlap bent corner parts of the mask frame, where each of the first guide units includes: a first base part coupled to the stage; a first cover part connected to the first base part and having a first opening defined therein; a first tilting part of which one portion is disposed inside the first cover part and another portion protrudes from the first cover part to an outside through the first opening; a first guide part connected to the first base part and the first tilting part; and a first elastic part connected to the first base part and the first tilting part.

In an embodiment, the mask frame may be characterized by contacting a top surface of the first tilting part of each of the first guide units and not contacting a surface of the stage, which faces the mask frame.

In an embodiment, the first tilting part may be characterized by being tiltable at any direction parallel to a major surface of the stage within the first opening.

In an embodiment, the first elastic part may be characterized by being provided with a spring having certain elasticity, and, when the mask frame contacts a top surface of the first tilting part of each of the first guide units, the first elastic part may be characterized by being contracted.

In an embodiment, the first elastic part may be characterized by being provided in plurality to be spaced apart from each other and with the first guide part interposed therebetween.

In an embodiment, the first guide part may be characterized by being surrounded by the first elastic part.

In an embodiment, in a plan view, a shape of the first guide part exposed through the first opening may be characterized by being one of circle or rectangle.

In an embodiment, the first tilting part may be characterized by defining a first hole having a hemispherical shape therein and a portion of the first guide part is coupled thereto, and the portion, coupled to the first hole, of the first guide part may be characterized by having a spherical shape.

In an embodiment, the mask assembly manufacturing device may be characterized by further including: second guide units configured to be disposed between the stage and the mask frame, and overlap the mask frame and spaced apart from the first guide units, where each of the second guide units may include: a second base part coupled to the stage; a second cover part connected to the second base part and having a second opening defined therein; a second tilting part of which a portion is disposed inside the second cover part and another portion protrudes from the first cover part to an outside through the second opening; a second guide part connected to the second base part and the second tilting part; and a second elastic part connected to the second base part and the second tilting part.

In an embodiment, the mask frame may be characterized by contacting a top surface of the second tilting part of each of the second guide units.

In an embodiment, the second tilting part may be characterized by being tiltable only in one direction within the second opening.

In an embodiment, the second elastic part may be characterized by being provided with a spring having certain elasticity, and, when the mask frame contacts a top surface of the second tilting part of each of the second guide units, the second elastic part may be characterized by being contracted.

In an embodiment, the second tilting part may be characterized by defining a second hole having a hexahedral shape therein and a portion of the second guide part is coupled thereto, and the portion, coupled to the second hole, of the second guide part may be characterized by having a hexahedral shape.

In an embodiment, the first tilting part and the second tilting part may be characterized by including stainless steel, or including a base part including the stainless steel and a coating layer covering the base part, and the coating layer may be characterized by including at least one of a Diamond-like Carbon (“DLC”) coating layer and a coating layer containing a silicon mixture material.

In an embodiment, the stage may be characterized by define air lines by which an inside of the stage and a top surface of the stage are penetrated, and an air flow injected through the air lines may be characterized by being provided to a rear surface of the mask frame, which faces the stage.

In an embodiment, the air lines may be characterized by overlapping the mask frame and being disposed between the first guide units and the second guide units.

In an embodiment, the stage may be characterized by further including first connection lines and second connection lines, which are connected to the air lines, and the first connection lines may penetrate the first base part and first tilting part, and the second connection lines may penetrate the second base part and second tilting part.

In an embodiment, the first guide units and the second guide units may be characterized by being disposed into stage grooves defined on the top surface of the stage, respectively, the first tilting part may be characterized by contacting the mask frame, while the second tilting part may be characterized by being spaced apart from the mask frame.

In an embodiment of the invention, a mask assembly manufacturing method includes: seating a mask frame on a stage, where the stage is inclined at a certain inclination with respect to a direction vertical to a major surface plane of a support part supporting the stage; providing an air flow to air lines defined in the stage to adjust a position of the mask frame; coupling sticks to the mask frame; and coupling a mask on the sticks, wherein, in the seating of the mask frame, the mask frame is directly disposed on guide units on the stage and on support units disposed on a lower portion of the stage and is spaced apart from the stage.

In an embodiment, the guide units may be characterized by overlapping corner parts of the mask frame, and each of the guide units may be characterized by including: a base part coupled to the stage; a cover part connected to the base part and having an opening defined therein; a tilting part of which a portion is disposed inside the cover part and another portion overlaps the opening to protrude outside; a guide part connected to the base part and the tiling part; and an elastic part connected to the base part and the tiling part, wherein the tilting part is tiltable at any direction parallel to a major surface of the stage in a state of contacting the mask frame.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a block diagram of a mask assembly manufacturing device according to an embodiment of the invention;

FIG. 2 illustrates a state where a mask frame is disposed on a mask stage shown in FIG. 1;

FIG. 3 is a plan view of the mask stage and the mask frame in a state where the front surface of the stage shown in FIG. 2 is viewed;

FIG. 4A is a cross-sectional view cut along a line I-I′ of FIG. 3;

FIG. 4B is a cross-sectional view of a guide unit according to an embodiment of the invention;

FIG. 4C is a plan view of a guide unit according to an embodiment of the invention;

FIG. 5A is a cross-sectional view illustrating a mask assembly manufacturing method according to an embodiment of the invention;

FIG. 5B is a cross-sectional view illustrating a mask assembly manufacturing method according to an embodiment of the invention;

FIG. 5C is a cross-sectional view illustrating a mask assembly manufacturing method according to an embodiment of the invention;

FIG. 5D is a plan view illustrating a mask assembly manufacturing method according to an embodiment of the invention;

FIG. 5E is a plan view illustrating a mask assembly manufacturing method according to an embodiment of the invention;

FIG. 6 is a plan view of a deposition device according to an embodiment of the invention;

FIG. 7 is a plan view of a display panel according to an embodiment of the invention;

FIG. 8 is a cross-sectional view of a display panel according to an embodiment of the invention;

FIG. 9 is a cross-sectional view for illustrating a process of providing a light emitting layer of a display panel according to an embodiment of the invention;

FIG. 10 is a plan view of a mask stage and mask frame in a state where the front surface of a stage is viewed according to another embodiment of the invention;

FIG. 11 is a cross-sectional view cut along II-Il′ shown in FIG. 10;

FIG. 12 is a plan view of a mask stage and mask frame in a state where the front surface of a stage is viewed according to still another embodiment of the invention; and

FIG. 13 is a cross-sectional view cut along III-III′ shown in FIG. 11.

### DETAILED DESCRIPTION

It will be understood that when an element or layer is referred to as being “on”, “connected to” or “coupled to” another element or layer, it can be directly on, connected or coupled to the other element or intervening third elements may be present.

Like reference numerals in the drawings refer to like elements. In addition, in the drawings, the thickness and the ratio and the dimension of the element are exaggerated for effective description of the technical contents. The term “and/or” includes any and all combinations of one or more of the associated items.

Terms such as “first”, “second”, and the like may be used to describe various components, but these components should not be limited by the terms. These terms are only used to distinguish one element from another. For instance, a first component may be referred to as a second component, or similarly, a second component may be referred to as a first component, without departing from the scope of the present disclosure. The singular expressions include plural expressions unless the context clearly dictates otherwise.

In addition, the terms such as “under”, “lower”, “on”, and “upper” are used for explaining associations of items illustrated in the drawings. The terms are used as a relative concept and are described with reference to the direction indicated in the drawings.

It should be understood that the terms “comprise” or “have” are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which example embodiments belong. In addition, it will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, embodiments of the invention will be described with reference to the accompanying drawings.

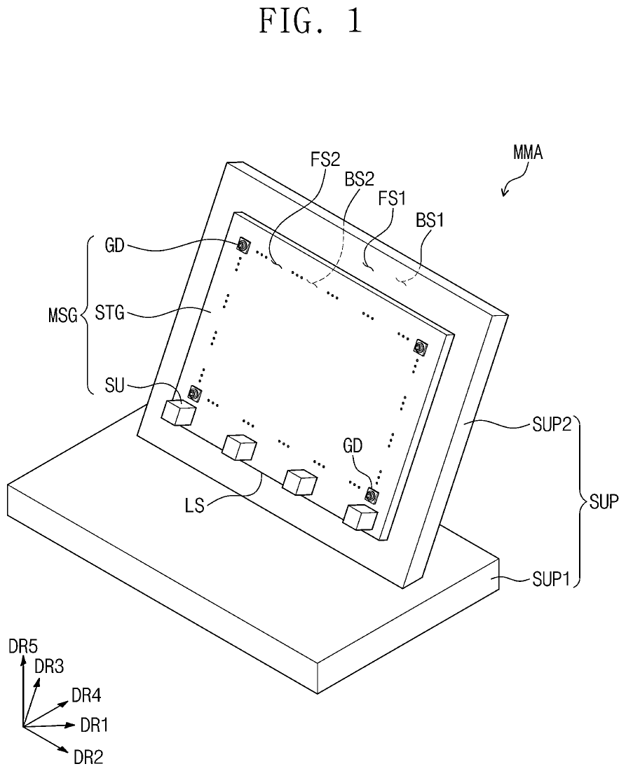

FIG. 1 is a block diagram of a mask assembly manufacturing device according to an embodiment of the invention.

Referring to FIG. 1, a mask assembly manufacturing device MMA according to an embodiment of the invention may include a support part SUP and a mask stage MSG disposed on the support part SUP. The support part SUP may be defined as a precision granite surface plate or stone table.

The support part SUP may include a first support part SUP1, and a second support part SUP2. The first part SUP1 may have a flat shape defined by a fourth direction DR4 and a second direction DR2 intersecting with the fourth direction DR4. The first support part SUP1 may has a cuboid shape with short sides extending in the fourth direction DR4 and long sides extending in the second direction DR2.

Hereinafter, a direction intersecting with a plane defined by the fourth and second directions DR4 and DR2 is defined as a fifth direction DR5. The fifth direction DR5 may substantially vertically intersect with the plane defined by the fourth and second directions DR4 and DR2.

The second support part SUP2 may be disposed on the first support part SUP1 to be connected to the first support part SUP1. The second support part SUP2 may have a rectangular flat shape and be coupled to the first support part SUP1 by being disposed to be inclined at a certain angle with respect to the fifth direction DR5 that is vertical to a plane defined by the top surface of the first support part SUP1.

The second support part SUP2 may be disposed to be inclined with respect to the fifth direction DR5 in a state where the second support part SUP2 has a plane defined by the second and third directions DR2, DR3. For example, the second support part SUP2 may be disposed to be inclined with respect to the fifth direction DR5 at an angle θ1 of about 2 to about 10 degrees. The second support part SUP2 may have sides extending in the third direction DR3, which is inclined with respect to the fifth direction DR5. The first and second support parts SUP1, SUP2 may be provided with the same material.

Hereinafter, a surface of the second support part SUP2, which faces upward in a state where the second support part SUP2 is inclined, is defined as a first front surface FS1, and a surface of the second support part SUP2, which faces the ground (downward), is defined as a first back surface BS1.

The mask stage MSG may be disposed on the second support part SUP2. The mask stage MSG may include a stage STG disposed on the second support part SUP2, a plurality of support units SU arranged on the stage STG, and a plurality of guide units GD arranged on the stage STG.

The stage STG may have a rectangular flat shape, and be disposed on the second support part SUP2 so as to form an angle θ1 at which the second support part SUP2 is inclined with respect to the top surface of the first support part SUP1. Accordingly, the stage STG may be disposed to be inclined with respect to the fifth direction DR5 at an angle of about 2 to about 10 degrees. The stage STG may be disposed on the first front surface FS1 of the second support part SUP2 to be fastened to the first front surface FS1.

Hereinafter, a surface of the stage STG, which faces upward in a state where the stage STG is inclined, is defined as a second front surface FS2, and a surface of the second support part STG, which faces the ground (downward), is defined as a second back surface BS2. The second back surface BS2 of the stage STG may be fastened to the first front surface FS1.

The support units SU and the guide units GD may be arranged on the second front surface FS2 of the stage STG. The support units SU and the guide units GD may be fastened to the stage STG. For example, the support units SU and the guide units GD may be fastened to the stage STG by means of fastening units such as screws. However, the embodiment is not limited thereto, and the components, which may be used for fastening the support units SU and the guide units GD to the stage STG, are not limited to the screws.

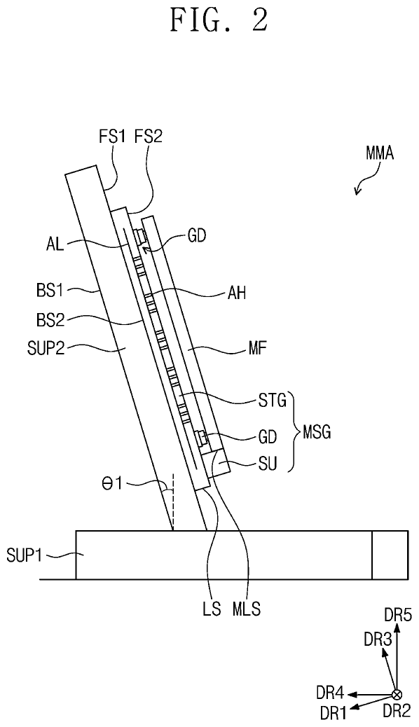

The support units SU may be disposed adjacent to a lower side LS of the stage STG that is adjacent to the first support part SUP1. The support units SU may be arranged along the second direction DR2. The support units SU may function to stably support the mask frame MF (see FIG. 2) disposed on the stage STG.

The guide units GD may be disposed adjacent to the corners of the stage STG, respectively. The corners of the stage STG may be defined as bent portions connecting the long sides and short sides of the stage STG. As an example, four guide units GD may be arranged adjacent to four corners of the stage STG, respectively.

Air holes AH may be defined in the stage STG according to an embodiment. The air holes AH may be arranged between two guide units GD spaced apart in the second direction DR2, and between two guide units GD spaced apart in the third direction DR3. The air holes AH may overlap the mask frame MF (see FIG. 2) in a plan view. The air holes AH may be a portion of air lines AL (see FIG. 2) defined in the second stage STG. In other words, the air lines AL may be defined as a pipe penetrating through the inside of the stage STG and the second surface FS2, and the air lines AL visually recognized when viewing the stage STG may be defined as the air holes AH.

The air lines AL and the air holes AH may provide paths through which an air current flows. For example, the air current provided from outside the stage STG through a motor or the like or provided from a motor or the like embedded in the support part SUP may be provided to the mask frame MF through the air lines AL and the air holes AH.

According to the invention, the stage STG may include an invar. The support units SU may include steel.

FIG. 2 illustrates a state where the mask frame is disposed on the mask stage shown in FIG. 1. In FIG. 2, the second support part SUP2 and the stage STG are illustrated as being inclined to the left side with respect to the fifth direction DR5.

Referring to FIG. 2, the second support part SUP2 and the stage STG may be inclined to form a certain angle θ1 with the fifth direction DR5. As aforementioned above, the certain angle θ1 may be about 2 to about 10 degrees.

The mask frame MF may be disposed on the stage STG. The mask frame MF may be disposed on the second front surface FS2 of the stage DTG.

The mask frame MF may be disposed on the stage DTG so as to correspond to an inclined angle θ1 of the second support part SUP2 and the stage STG. The mask frame MF may be cradled on the support units SU arranged in the lower side LS of the stage STG. As the support units SU support a lower side MLS of the mask frame MF, the mask frame MF may be stably disposed on the stage STG.

The guide units GD may overlap the mask frame MF in a plan view. When the mask frame MF is disposed on the support units SU, the mask frame MF and the guide units GD may contact each other. Here, the mask frame MF may be spaced apart from the stage STG.

In the stage STG, the air lines AL penetrating through the inside and the second front surface FS2 of the stage STG may be defined. The air lines AL may be connected by means of one pipe.

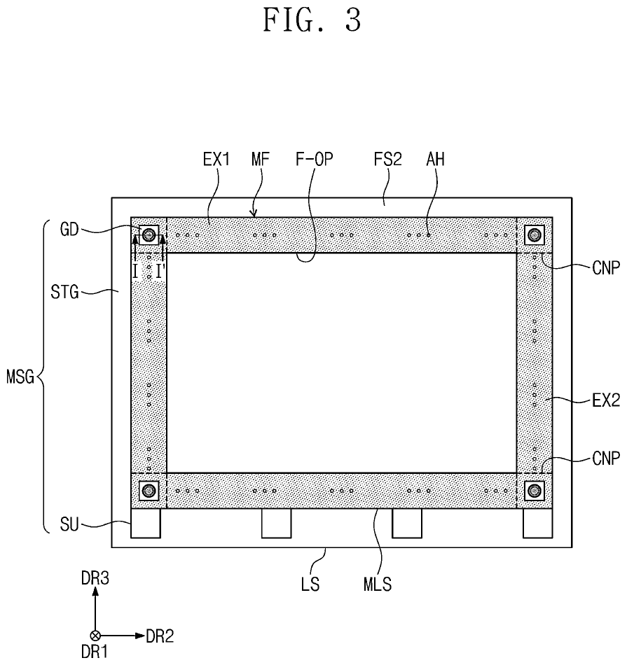

FIG. 3 is a plan view of the mask stage and the mask frame in a state where the front surface of the stage shown in FIG. 2 is viewed. As used herein, the “plan view” is a view in a direction (e.g., first direction DR1) perpendicular to a major surface plane of the mask frame MF.

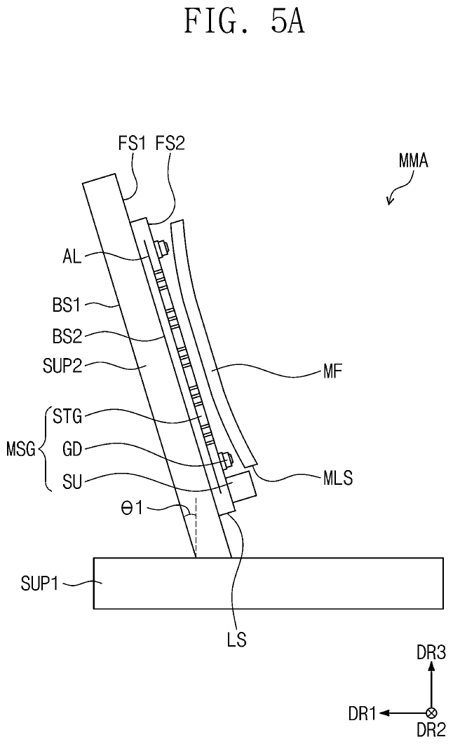

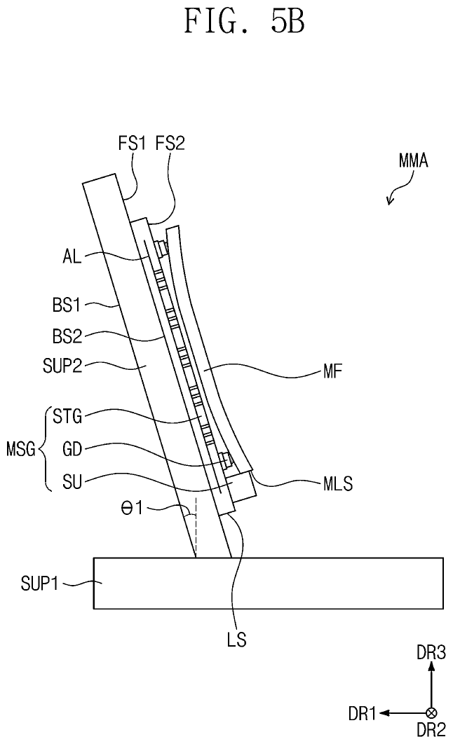

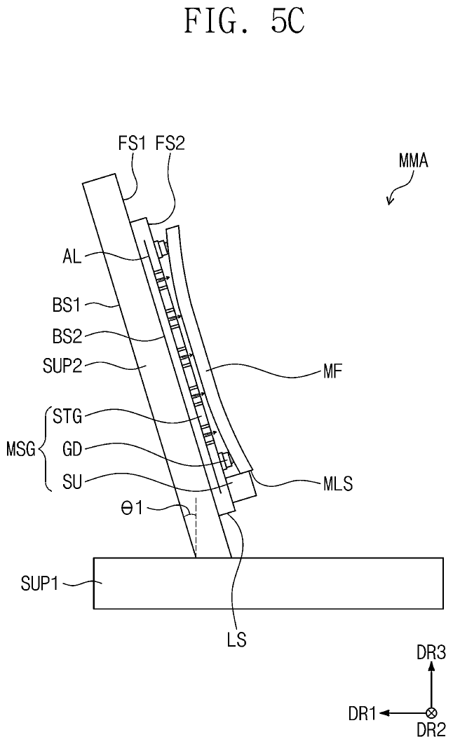

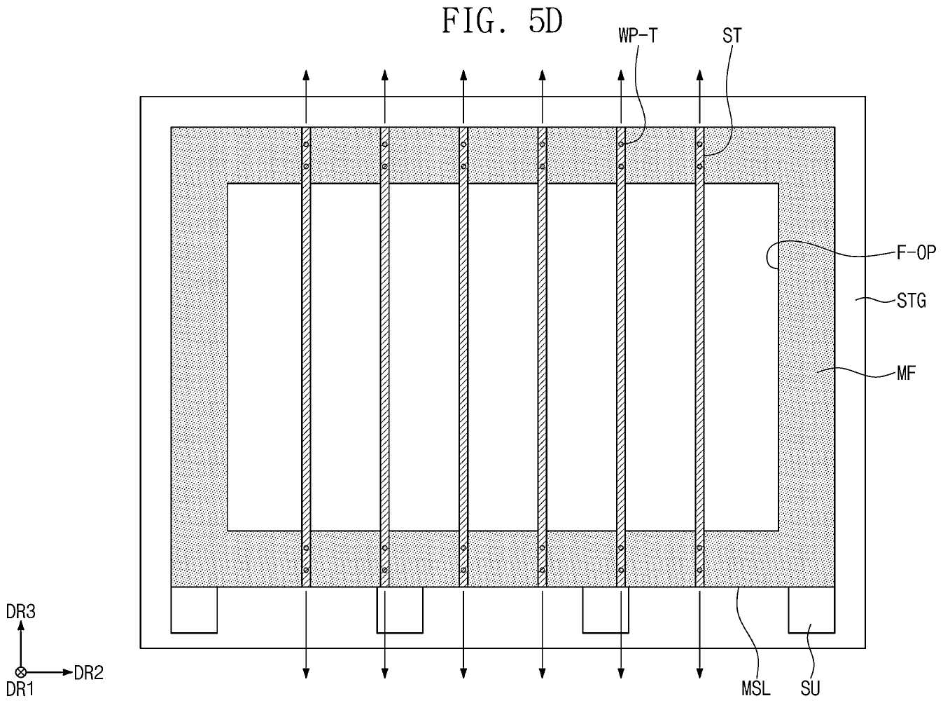

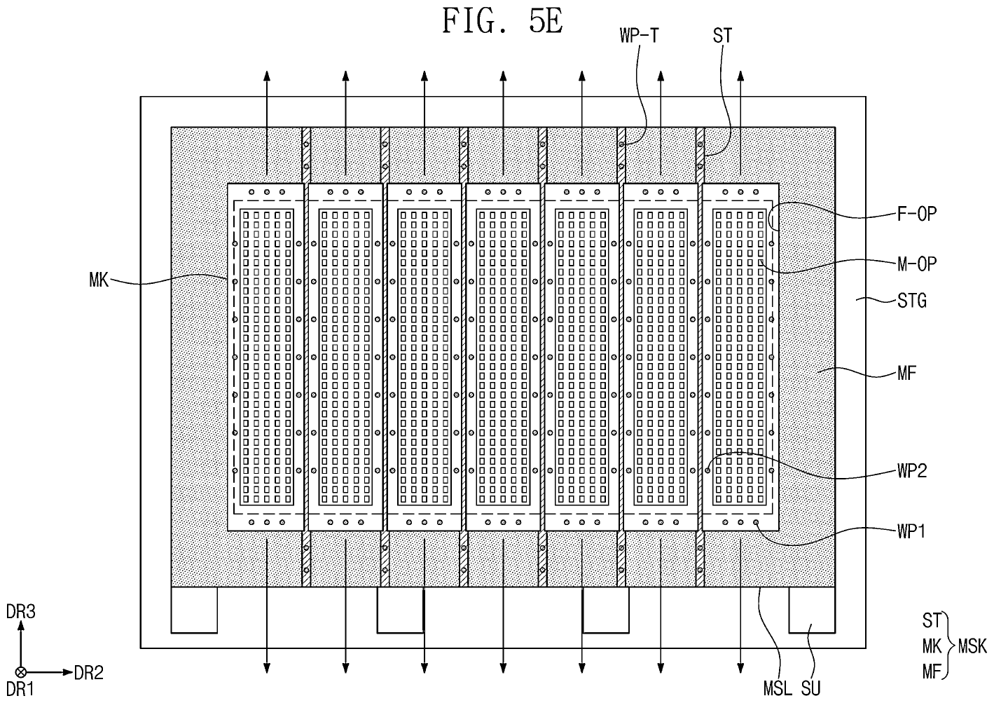

Referring to FIG. 3, the mask frame MF may be disposed on the stage STG. The mask frame MF may provide a frame to which a plurality of masks MK (see FIG. 5E) to be described below are coupled.

When viewing the second front surface FS2 of the stage STG ( ) the mask frame MF may have a rectangular frame shape. The mask frame MF may define a frame opening F-OP of a rectangular shape therein. The frame opening F-OP may be provided by penetrating through the rear surface from the front surface of the mask frame MF.

The mask frame MF may include corner portions CNP defined by the bent portions of the frame shape. Since the mask frame MF may have the rectangular frame shape, four corner portions CNP may be defined in the mask frame MF. The corner portions CNP may be arranged adjacent to the corners of the stage STG, respectively.

Hereinafter, the configurations of the mask stage MSG and the mask frame MF will be described in a state where the mask stage MSG and the mask frame MF are disposed in parallel with the second direction DR2 and the third direction DR3.

The mask frame MF may include first extension parts EX1 that extend in parallel in the second direction DR2 and face each other in the third direction DR3, and second extension parts EX2 that extend in parallel in the third direction DR3 and face each other in the second direction DR2. The second direction DR2 may be defined as one direction, and the third direction DR3 may be defined as another direction that intersects with the one direction.

The second extension parts EX2 may be bent to extend from the ends of the first extension parts EX1 in the third direction DR3. In addition, the first extension parts EX1 may be bent to extend from the ends of the second extension parts EX2 in the second direction DR2. The rectangular frame shape of the mask frame MF may be defined by the second extension parts EX2. Areas in which the ends of the first extension parts EX1 overlap the ends of the second extension parts EX2 in a plan view are displayed by dotted lines, and portions displayed with bold dotted lines may be defined as the corner parts CNP.

The width of each of the first extension parts EX1 may be the same as the width of each of the second extension parts EX2. The width in the specification may be defined as a value measured in a direction that intersects with the extension direction of the corresponding component. Accordingly, the width of each of the first extension parts EX1 may be defined as a value measured in the third direction DR3, and the width of each of the second extension parts EX2 may be defined as a value measured in the second direction DR2.

According to an embodiment, when viewing the second front surface FS2 of the stage STG, the guide units GD may overlap the mask frame MF. More specifically, the guide units GD each may overlap the corresponding corner portion CNP in a plan view.

The mask frame MF is seated on the mask stage MSG, a component contacting the mask frame MF may be the support units SU and the guide units GD. A portion of the mask frame MF substantially contacting the guide units GD is the corner parts CNP, and the other portion other than the portion contacting the corner parts CNP may be spaced apart from the stage STG.

Therefore, according to the invention, when the mask frame MF is seated on the mask stage MSG, a friction force generated by the contact between the stage STG and the mask frame MF may be reduced. Accordingly, even though the mask frame MF is disposed on the stage STG that is inclined at a certain angle θ1 with respect to a direction vertical to the plane as shown in FIG. 2, the shape of the mask frame MF may be prevented from being deformed by the friction force due to the contact between the stage STG and the mask frame MF.

According to an embodiment, when viewing the second front surface FS2 of the stage STG, the air holes AH may overlap the mask frame MF in a plan view. Furthermore, according to an embodiment, the air holes AH may be spaced apart from the corner parts CNP. Some air holes AH may overlap the first extension parts EX1, respectively, and be disposed between two guide units GD spaced apart in the second direction DR2. The other air holes AH may overlap the first extension parts EX2, respectively, and be disposed between two guide units GD spaced apart in the second direction DR3.

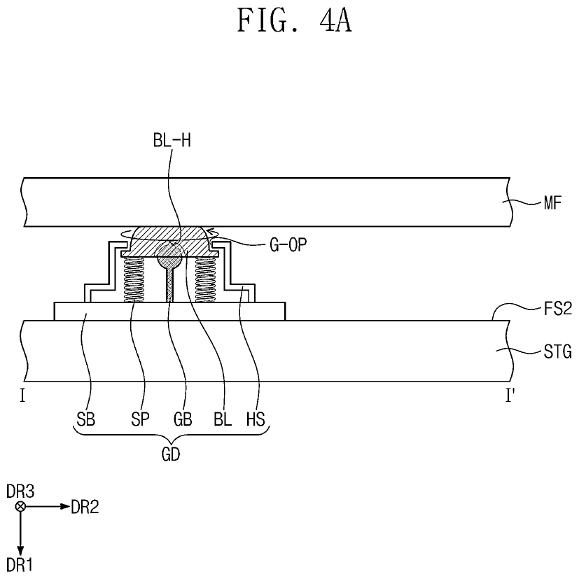

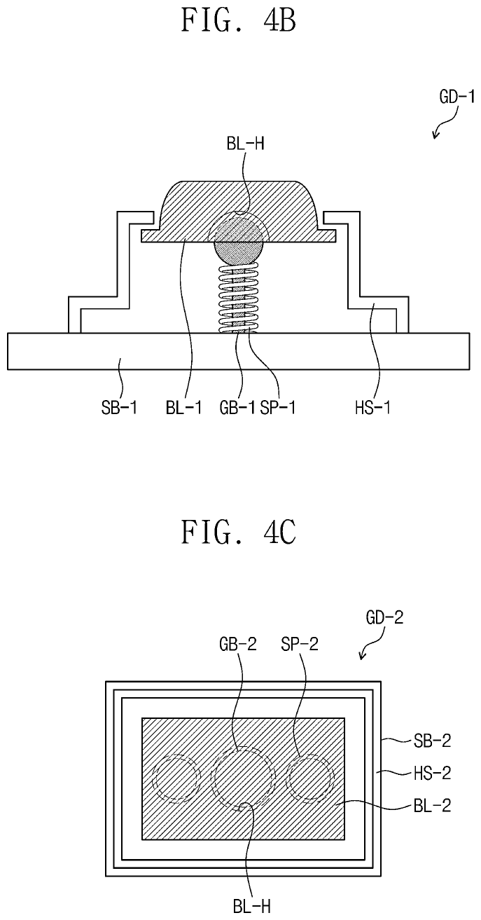

FIG. 4A is a cross-sectional view cut along a line I-I′ of FIG. 3.

FIG. 4A illustrates the guide unit GD disposed on the second front surface FS2 of the stage STG and the mask frame MF disposed on the guide unit GD.

According to an embodiment, the guide unit GD may include a base part SB, a cover part HS, a tilting part BL, a guide part GB, and an elastic part SP.

The base part SB may be disposed on the stage STG. The base part SB may be fastened on the stage STG by fastening units such as screws. The base part SB may be a basal layer on which other components of the guide unit GD may be disposed.

The cover part HS may be coupled to the base part SB to define the appearance of the guide unit GD. The cover part HS may have a guide opening G-OP defined therein through which a portion of the tilting part BL to be described below may be exposed to the outside. The cover part HS and the base part SB may include one of plastic and steel.

The tilting part BL may be a component configured to contact the mask frame MF. A portion of the tilting part BL may be disposed inside the cover part HS. The other portion of the tilting part BL may protrude from the cover part HS to the outside of the cover part HS through the guide opening G-OP of the cover part HS. As the portion of the tilting part BL disposed inside the cover part HS has a width larger than a width of the guide opening G-OP in a direction parallel to the second front surface FS, the portion of the tilting part BL may prevent the tilting part BL from being separated out of the cover part HS. According to an embodiment, the shape of the tilting part BL in a plan view may be one of a circular or elliptical shape.

The tilting part BL may define a hole BL-H therein. The hole BL-H may be coupled with a portion of the guide part GB. In the embodiment, the hole BL-H may have a hemispherical shape.

The guide part GB may be disposed between the base part SB and the tilting part BL. A portion of the guide part GB may be coupled to the hole BL-H of the tilting part BL, and the other portion of the guide part GB may be fastened to the base part SB.

According to the embodiment, a portion of the guide part GB coupled to the hole BL-H of the tiling part BL may have a spherical shape. In addition, the other portion of the guide part GB connected to the spherical shape may have a cylindrical shape.

According to the embodiment, as the hole BL-H of the tilting part BL has the hemispherical shape and the guide part GB coupled to the hole BL-H has the spherical shape, the tilting part BL may be tilted at any direction parallel to a major surface of the stage STG within the cover part HS. For convenience of description, the radius at which the tilting part BL may be rotated is shown with an arrow. According to an embodiment, when the mask frame FM is disposed on the tilting part BL, the tilting part BL is tilted within the cover part HS so as to correspond to a moving operation state of the mask frame FM and thus the mask frame FM may be easily cradled on the tilting part BL.

According to an embodiment, the tilting part BL may include stainless steel. The tilting part BL according to an embodiment may include a base layer including stainless steel and a coating layer covering the base layer. The coating layer may be a plasma-processed coating layer. For example, the coating layer may be a Diamond-like Carbon (DLC) coating layer. In another embodiment, the coating layer may be a mixture of the DLC coating layer and a coating layer containing a silicon mixture material, and is not limited to one embodiment.

The elastic part SP may be provided in plurality and be spaced apart from each other with the guide part GB interposed therebetween. One end of the elastic part SP may be connected to the base part SB and the other end of the elastic part SP may be connected to the tilting part BL. The elastic part SP may be provided with a spring having certain elasticity. The elastic part SP may be contracted when the mask frame MF is seated on the tilting part BL and be released when being unseated. Accordingly, even when a plurality of mask frames are seated and unseated in mask assembly manufacturing processes, the tilting part BL may be prevented from being sagged toward the base part SB.

According to the invention, when the mask frame MF is seated on the stage STG, a component substantially contacting the mask frame MF is the tilting part BL in the guide unit GD, and as the tilting part BL is tiltable at any direction parallel to a major surface of the stage STG, a friction force applied to the mask frame MF may be reduced.

FIG. 4B is a cross-sectional view of a guide unit according to an embodiment of the invention.

Referring to FIG. 4B, the guide unit GD-1 according to an embodiment may include a base part SB-1, a cover part HS-1, a tilting part BL-1, a guide part GB-1, and an elastic part SP-1. The description of the base part SB-1, the cover part HS-1, the tilting part BL-1 and the guide part GB-1 may correspond to that of the base part SB, the cover part HS, the tilting part BL and the guide part GB in FIG. 4A, and thus repetitive descriptions will be omitted.

One end of the elastic part SP-1 according to an embodiment may be connected to the base part SB-1 and the other end of the elastic part SP-1 may be connected to the tilting part BL-1. The elastic part SP-1 may be provided with a spring having certain elasticity.

According to the embodiment, the guide part SB-1 may be disposed in an inner space of the elastic part SP-1 having a spring shape. Accordingly, the guide part GB-1 may be surrounded by the elastic part SP-1.

FIG. 4C is a plan view of a guide unit according to an embodiment of the invention. FIG. 4C illustrates the shape of the guide unit GD-2 in a plan view.

Referring to FIG. 4C, the guide unit GD-2 according to the embodiment may include a base part SB-2, a cover part HS-2, a tilting part BL-2, a guide part GB-2, and an elastic part SP-2. The description of the base part SB-2, the cover part HS-2, the tilting part SP-1 and the guide part GB-1 may correspond to that of the base part SB, the cover part HS, the tilting part SP and the guide part GB in FIG. 4A, and thus repetitive descriptions will be omitted.

According to an embodiment, the shape of the tilting part BL-2 in a plan view may be a quadrangle. However, the embodiment is not limited thereto. The shape of the tilting part BL-2 in a plan view may be one of a rectangle and a polygon, and is not limited thereto.

FIG. 5A is a cross-sectional view illustrating a mask assembly manufacturing method according to an embodiment of the invention. FIG. 5B is a cross-sectional view illustrating a mask assembly manufacturing method according to an embodiment of the invention. FIG. 5C is a cross-sectional view illustrating a mask assembly manufacturing method according to an embodiment of the invention. FIG. 5D is a cross-sectional view illustrating a mask assembly manufacturing method according to an embodiment of the invention. FIG. 5E is a plan view illustrating a mask assembly manufacturing method according to an embodiment of the invention.

FIGS. 5A to 5E illustrate, step by step, a mask assembly manufacturing method for manufacturing a mask assembly using the mask assembly manufacturing device described with reference to FIGS. 1 to 4A. For the same/similar components as FIGS. 1 to 4A, the same/similar reference numerals are used and their repetitive descriptions will be omitted.

Referring to FIG. 5A, the mask assembly manufacturing method according to an embodiment may include a step for seating the mask frame MF on the mask assembly manufacturing device MMA.

The mask assembly manufacturing device MMA may include the support part SUP and the mask stage MSG disposed on the support part SUP.

The support part SUP may include the first support part SUP1, and the second support part SUP2. The first part SUP1 may have a flat shape defined by the fourth direction DR4 and the second direction DR2 intersecting with the fourth direction DR4.

The second support part SUP2 may be disposed on the first support part SUP1 to be connected to the first support part SUP1. The second support part SUP2 may have a rectangular flat shape and be coupled to the first support part SUP1 by being disposed to be inclined at a certain angle θ1 with respect to the fifth direction DR5 that is vertical to a plane defined by the top surface of the first support part SUP1. For example, the second support part SUP2 may be disposed to be inclined with respect to the fifth direction DR5 at an angle of about 2 to about 10 degrees. The first and second support parts SUP1, SUP2 may be provided with the same material. Here, the fifth direction DR5 may be opposite to a gravity direction.

The mask stage MSG may be disposed on the second support part SUP2. The mask stage MSG may include a stage STG disposed on the second support part SUP2, a plurality of support units SU arranged on the stage STG, and a plurality of guide units GD arranged on the stage STG. The stage STG may include the air lines AL penetrating through the inside and the second front surface FS2 of the stage STG.

The mask frame MF may be seated on the stage STG so as to correspond to an angle θ1 at which the stage STG and the second support part SUP2 are inclined. The mask frame MF may be conveyed by a robot arm or the like so as to be able to be disposed on the stage STG.

In an initial state, the mask frame MF may be provided as a rectangular frame as shown in FIG. 3. However, when being seated on the stage STG in a state vertical to a plane, the mask frame MF may be seated on the stage STG in a state different from an initially manufactured state, namely, in a state where at least a portion of the rectangular frame is distorted by the load of the mask frame MF itself or grip pressure applied by a robot arm, etc. FIGS. 5A to 5E illustrate the mask frame MF of which a portion is deformed from the initial state.

Then, referring to FIG. 5B, the mask assembly manufacturing method according to an embodiment may include a step for seating the mask frame GD on the support units SU and the guide units GD.

The mask frame MF may be seated on the support units SU and the guide units GD through the robot arm or the like. The lower side MLS of the mask frame MF may contact the support units SU. As the support units SU support the lower side MLS of the mask frame MF, the mask frame MF may be stably disposed on the stage STG.

The corner portions CNP (see FIG. 3) of the mask frame MF may contact the guide units GD. Accordingly, when the mask frame MF is seated on the mask stage MSG, the mask frame MF may directly contact the support units SU and the guide units GD, and be spaced apart from the stage STG. Accordingly, the shape of the mask frame MF may be prevented from being deformed by a friction force generated when the mask frame MF is directly put on the stage STG.

Furthermore, in a transferred/conveyed process, when a portion of the mask frame MF is deformed and the mask frame MF directly contacts the stage STG without support from the guide units GD, deformation may be prevented from being generated by a gap between a loose portion and a portion contacting the stage STG in the mask frame MF.

In addition, according to the mask assembly manufacturing device MMA of the invention, as the mask frame MF is disposed on the guide units GD, a phenomenon in which the mask frame MF is sagged by the load of the mask frame MF itself may be improved.

Then, referring to FIG. 5C, the mask assembly manufacturing method according to an embodiment may include a step for adjusting the position of the mask frame MF.

In the step for adjusting the position of the mask frame MF, an air flow may be provided to the air lines AL defined in the stage STG, and the air flow may be injected to the rear surface of the mask frame MF through the air lines AL. Here, the position of the mask frame MF may be finely adjusted in μm units in a state where the load of the mask frame MF applied to the support units SU and the guide units GD is reduced and the friction force between the guide units GD and the mask frame MF is reduced.

After the position of the mask frame MF is finely adjusted, the air flow may be controlled by a motor or the like and the mask frame MF may be seated on the support units SU and the guide units GD again.

Then, referring to FIG. 5D, the mask assembly manufacturing method according to an embodiment may include a step for coupling sticks ST to the mask frame MF.

The sticks ST may be disposed on the mask frame MF. Each of the sticks ST may be extend along the third direction DR3 and spaced apart from each other along the second direction DR2.

One portion of each of the sticks ST may overlap a top portion of the mask frame MF, and the other portion of each of the sticks, which is spaced apart from the one portion along the third direction DR3, may overlap a bottom portion of the mask frame MF in a plan view.

The method may further include a step for tensioning the sticks ST before each of the sticks ST is coupled to the mask frame MF. The sticks ST may be coupled to the mask frame MF in a state where the one portion and the other portion of each of the sticks ST are tensioned in the third direction DR3. According to an embodiment, grooves into which the one portion and the other portion of each of the sticks may be fit may be defined in the mask frame MF.

Each of the sticks ST may be coupled to the mask frame MF in a state of being tensioned along the third direction DR3. The sticks ST may be coupled to the mask frame MF through a welding process. As an example, welding bumps WP-T are illustrated which are provided on the one portion and the other portion of each of the sticks ST through the welding process.

Then, referring to FIG. 5E, the method may include a step for coupling masks MK to the mask frame MF. Each of the masks MK may extend along the third direction DR3 and be spaced apart from each other along the second direction DR2.

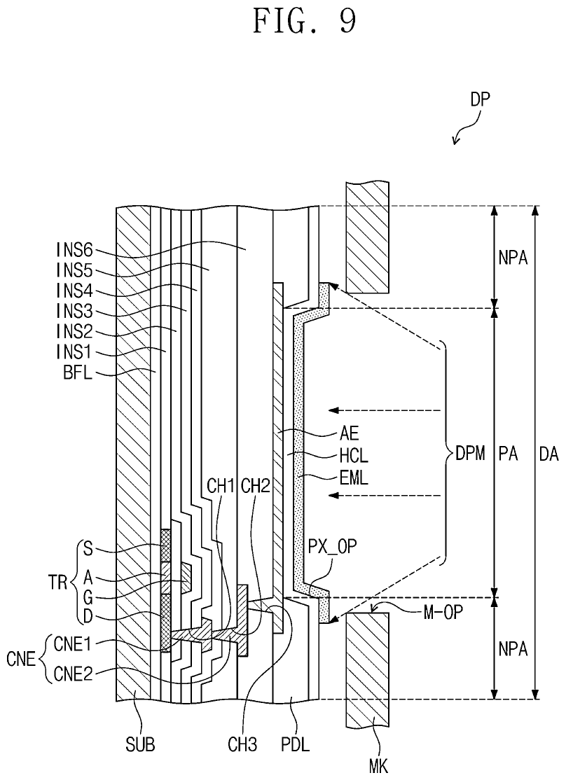

The masks MK may be fine metal masks (“FMMs”) including an invar. Each of the masks MK may include a deposition opening M-OP to be used for providing the light emitting layer EML (see FIG. 9) among the components included in the display panel DP (see FIG. 9). The deposition opening M-OP may be provided in plural to be arranged along the second direction DR2 and the third direction DR3.

One portion of each of the masks MK may overlap the top portion of the mask frame MF, and the other portion of each of the sticks, which is spaced apart from the one portion along the third direction DR3, may overlap the bottom portion of the mask frame MF in a plan view. A left portion of the mask MK disposed in the leftmost side may overlap the mask frame MF, and a right portion of the mask MK disposed in the rightmost side may overlap the mask frame MF. In addition, the masks MF adjacent along the second direction DR2 may overlap the corresponding sticks ST in a plan view.

The method may further include a step for tensioning the masks MK before each of the masks MK are coupled to the mask frame MF. The masks MK may be coupled to the mask frame MF in a state where the one portion and the other portion of each of the masks MK are tensioned in the third direction DR3 . . .

Each of the masks MK may be coupled to the mask frame MF in a state of being tensioned along the third direction DR3. The masks MK may be coupled to the mask frame MF through a welding process. As an example, first welding bumps WP1 may be formed in portions of the masks MK, which overlap the mask frame MF, and second welding bumps WP2 may be formed in portions of the masks MK, which overlap the sticks ST in a plan view.

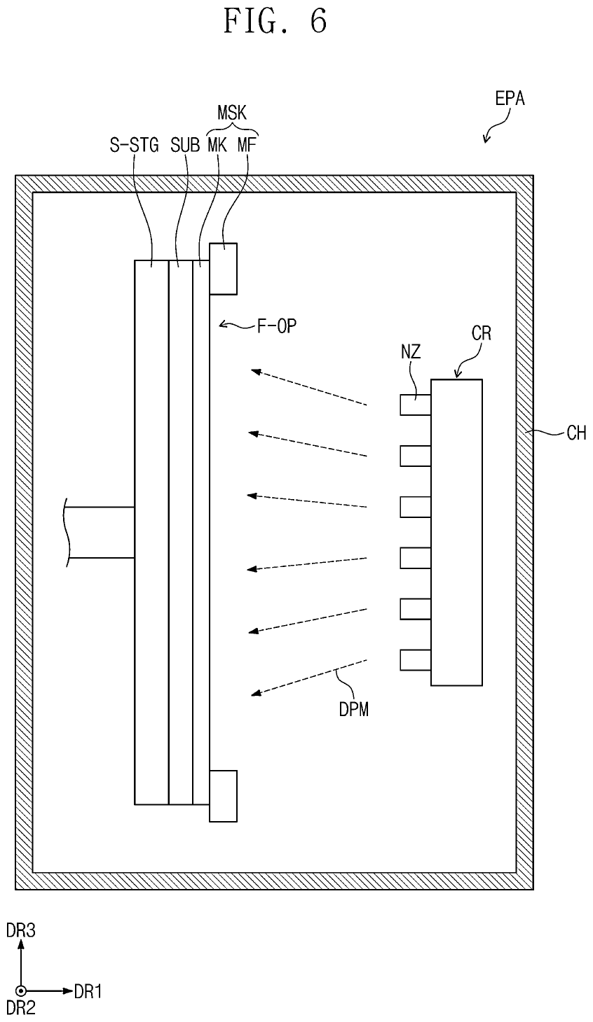

In the specification, a state where the sticks ST and the masks MK are coupled to the mask frame MF may be defined as a mask assembly MSK. Hereinafter, referring to FIGS. 6 to 9, a process of providing the light emitting layer EML (see FIG. 9) by means of the mask assembly MSK through a deposition process will be described. The mask assembly MSK is provided by means of the mask assembly manufacturing device MMA according to the invention.

FIG. 6 is a cross-sectional view of a deposition device according to an embodiment of the invention; FIG. 6 illustrates the deposition device including the mask assembly manufactured by the mask assembly manufacturing device shown in FIG. 1.

Referring to FIG. 6, the deposition device EPA may be defined as a vertical deposition device. The deposition device may include a chamber CH, a substrate stage S-STG, the mask assembly MSK, a crucible CR, and a plurality of nozzles NZ. The chamber CH may be defined as a vacuum chamber. The substrate stage S-STG, the mask assembly MSK, the crucible CR, and the nozzles NZ may be disposed in the chamber CH.

The substrate stage S-STG, the mask assembly MSK, and the crucible CR may be disposed in parallel with the third direction DR3. The substrate stage S-STG, the mask assembly MSK, and the crucible CR may be arranged in the first direction DR1. The mask assembly MSK may be disposed between the substrate stage S-STG and the crucible CR.

FIG. 6 illustrates that the substrate stage S-STG extends in the third direction DR3, but the embodiment is not limited thereto. In another embodiment, the deposition process may be performed on the substrate stage S-STG in a state where the substrate stage S-STG is inclined at a certain angle θ1 with respect to the third direction DR3 within the chamber CH, but the embodiment is not limited thereto.

The nozzles NZ may be connected to one surface of the crucible CR facing the mask assembly MSK. Although not shown, a deposition material DPM may be disposed within the crucible CR, and a heating wire for heating the deposition material DPM may be disposed in the crucible CR.

A substrate SUB may be disposed on the substrate stage S-STG. The substrate SUB may be disposed between the substrate stage S-STG and the mask assembly MSK. The mask assembly MSK may be disposed on the substrate SUB. The mask assembly MSK may include the masks MK, the sticks ST (see FIG. 5E) and the mask frame MF.

The deposition material DPM heated in the crucible CR is evaporated and the evaporated deposition material DPM may be injected through the nozzles NZ. The deposition material DPM may be provided onto the substrate SUB through the frame opening F-OP and the deposition openings M-OP (see FIG. 5E) defined in the masks (see FIG. 5E).

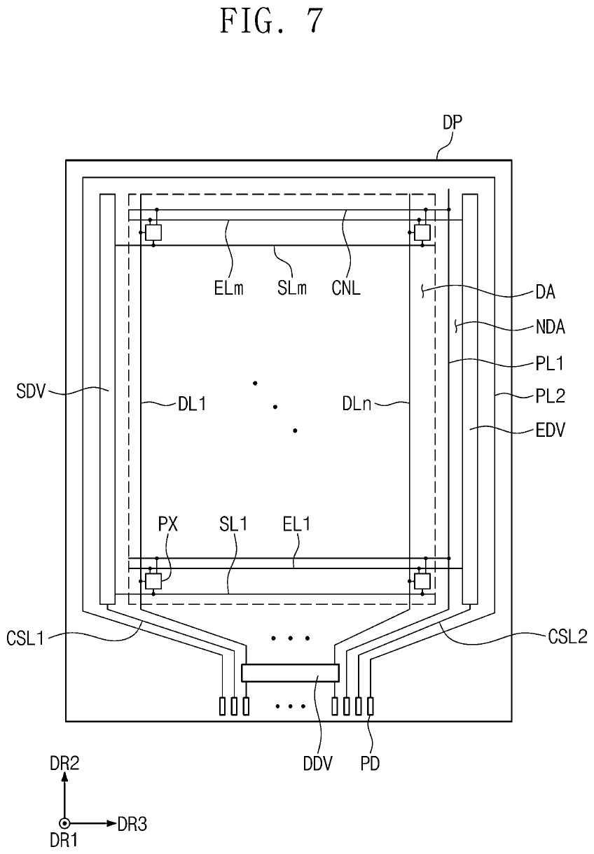

FIG. 7 is a plan view of a display panel manufactured using the deposition device shown in FIG. 6.

Referring to FIG. 7, the display panel DP may have a rectangular shape having long sides extending in the second direction DR2 and short sides extending in the third direction DR3, but the shape of the display panel DP is not limited thereto. The display panel DP may include a display part DA and a non-display part NDA surrounding the display part DA.

The display panel DP may be an emissive display panel. The display panel DP may be an organic light emitting display panel or an inorganic light emitting display panel. A light emitting layer of the organic light emitting display panel may include an organic light emitting material. A light emission layer of the inorganic light emitting display panel may include quantum dots, quantum rods, or the like. Hereinafter, the display panel DP will be described as an organic light emitting display panel.

The display panel DP may include a plurality of pixels PX, a plurality of scan lies SL1 to SLm, a plurality of data lines DLI to DLn, a plurality of emission lines EL1 to ELm, first and second control lines CSL1 and CSL2, power lines PL1, PL2, connection lines CNL and a plurality of pads PD. Here, m and n are natural numbers.

The pixels PX may be disposed in the display part DA. Each of a scan driver SDV and an emission driver EDV may be disposed in the non-display part NDA adjacent to the long sides of the display panel DP. The data driver DDV may be disposed in the non-display part NDA adjacent to one of the short sides of the display panel DP. In a plan view, the data driver DDV may be adjacent to a lower portion of the display panel DP.

The scan lines SL1 to SLm may extend in the third direction DR3 to be connected to the pixels PX and the scan driver SDV. The data lines DLI to DLn may extend in the second direction DR2 to be connected to the pixels PX and the data driver DDV. The emission lines EL1 to ELm may extend in the third direction DR3 to be connected to the pixels PX and the emission driver EDV.

The first power line PL1 may extend in the second direction DR2 to be disposed in the non-display part NDA. The first power line PL1 may be disposed between the display part DA and the emission driver EDV, but is not limited thereto and may be disposed between the display part DA and the scan driver SDV.

The connection lines CNL may extend in the third direction DR3 and be arranged in the second direction DR2. The connection lines CNL may be connected to the first power PL1 and the pixels PX. A first voltage may be applied to the pixels PX through the first power line PL1 and the connection lines CNL that are connected to each other.

The second power line PL2 may be disposed in the non-display part NDA. The second power line PL2 may extend along the long sides of the display panel DP and the other short side of the display panel DP, beside which the data driver DDV is not disposed. The second power line PL2 may be disposed in the outer side than the scan driver SDV and the emission driver EDV.

Although not shown, the second power line PL2 may extend towards the display part DA to be connected to the pixels PX. A second voltage having a lower level than the first voltage may be applied to the pixels PX through the second power line PL2.

The first control line CSL1 may be connected to the scan driver SDV and extend towards a lower portion of the display panel DP in a plan view. The second control line CSL2 may be connected to the emission driver EDV and extend to the lower portion of the display panel DP in a plan view. The data driver DDV may be disposed between the first control line CSL1 and the second control line CSL2.

The pads PD may be disposed on the display panel DP. The pads PD may be disposed more adjacent to the lower end of the display panel DP than the data driver DDV. The data driver DDV, the first power line PL1, the second power line PL2, the first control line CSL1, and the second control line CSL2 may be connected to the pads PD. The data lines DLI to DLn may be connected to the data driver DDV, and the data driver DDV may be connected to the pad PD corresponding to the data lines DLI to DLn.

Although not shown, a timing controller for controlling the operations of the scan driver SDV, the data driver DDV, and the light emission driver EDV, and a voltage generation part for generating the first and second voltages may be disposed on a printed circuit board. The timing controller and the voltage generation part may be connected to the corresponding pads PD through the printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DLI to DLn. The emission driver EDV may generate a plurality of emission signals and the emission signals may be applied to the pixels PX through the emission lines EL1 to ELm.

The pixels PX may receive the data voltages in response to the scan signals. The pixels PX may display an image by emitting light with luminances corresponding to the data voltages in response to the emission signals. An emission time of the pixels PX may be controlled by the emission signals.

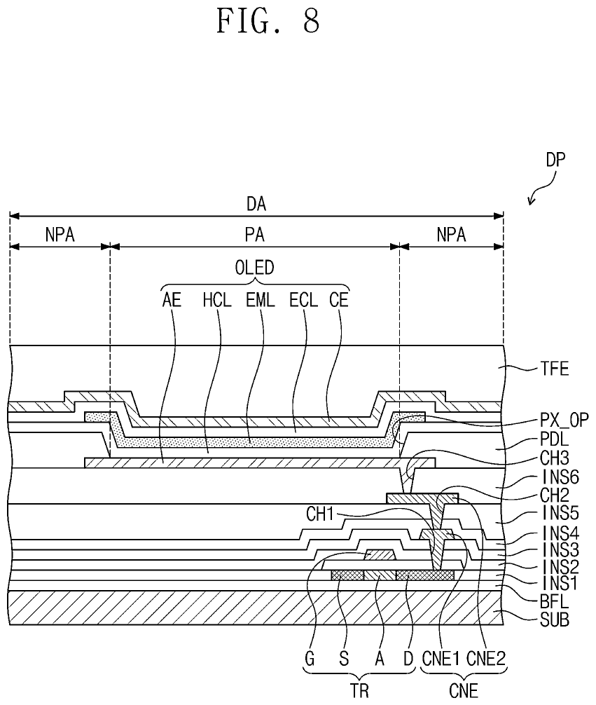

FIG. 8 illustrates an example cross section of any one pixel shown in FIG. 7.

The pixel PX may be disposed on the substrate SUB and include a transistor TR and a light emitting element OLED. The light emitting element OLED may include a first electrode AE, a second electrode CE, a hole control layer HCL, an electron control layer ECL, and a light emitting layer EML. The first electrode AE may be an anode, and the second electrode CE may be a cathode.

The transistor TR and the light emitting element OLED may be disposed on the substrate SUB. Although one example transistor TR is illustrated, the pixel PX may substantially include a plurality of transistors for driving the light emitting element OLED, and at least one capacitor.

The display part DA may include a light emitting part PA corresponding to the pixel PX and non-light emitting parts NPA around the light emitting part PA. The light emitting element OLED may be disposed in the light emitting part PA.

A buffer layer BFL may be disposed on the substrate SUB, and the buffer layer BFL may be an inorganic layer. A semiconductor pattern may be disposed on the buffer layer BFL. The semiconductor pattern may include polysilicon. However, the embodiment is not limited thereto, and the semiconductor pattern may include amorphous silicon or metal oxide.

The semiconductor pattern may be doped with an N-type dopant or a P-type dopant. The semiconductor pattern may include a high-doped area and a low-doped area. The conductivity of the high-doped area may be greater than the conductivity of the low-doped area, and substantially serve as source and drain electrodes of the transistor TR. The low-doped area may substantially correspond to an active area (or a channel) of the transistor.

The source S, the active area A, and the drain D of the transistor TR may be provided from the semiconductor pattern. A first insulation layer INS1 may be disposed on the semiconductor pattern. A gate G of the transistor TR may be disposed on the first insulation layer INS1. A second insulation layer INS2 may be disposed on the gate G. A third insulation layer INS3 may be disposed on the second insulation layer INS2.

A connection electrode CNE may be disposed between the transistor TR and the light emitting element OLED to connect them with each other. The connection electrode may include a first connection electrode CNE1 and a second connection electrode CNE2.

The first connection electrode CNE1 may be disposed on the third insulation layer INS3, and be connected to the drain D through a first contact hole CH1 defined in the first to third insulation layers INS1 to INS3. A fourth insulation layer INS4 may be disposed on the first connection electrode CNE1. A fifth insulation layer INS5 may be disposed on the fourth insulation layer INS4.

The second connection electrode CNE2 may be disposed on the fifth insulation layer INS5. The second connection electrode CNE2 may be connected to the first connection electrode CNE1 through a second contact hole CH2 defined in the fifth insulation layer INS5. A sixth insulation layer INS6 may be disposed on the second connection electrode CNE2. The first insulation layer INS1 to the sixth insulation layer INS6 may be inorganic layers or organic layers.

The first electrode AE may be disposed on the sixth insulation layer INS6. The first electrode AE may be connected to the second connection electrode CNE2 through a third contact hole CH3 defined in the sixth insulation layer INS6. A pixel definition layer PDL configured to expose a certain portion of the first electrode AE may be disposed on the first electrode AE and the sixth insulation layer INS6. In the pixel definition layer PDL, a display opening PX_OP may be defined to expose the certain portion of the first electrode AE.

The hole control layer HCL may be disposed on the first electrode AE and the pixel definition layer PDL. The hole control layer HCL may be commonly disposed in the light emitting part PA and the non-light emitting part NPA. The hole control layer HCL may include a hole transport layer and a hole injection layer.

The light emitting layer EML may be disposed on the hole control layer HCL. The light emitting layer EML may be disposed in an area corresponding to the display opening PX_OP. The light emitting layer EML may include an organic material and/or inorganic material. The light emitting layer EML may generate light of one of red, green, and blue colors. The light emitting layer EML may be provided through a deposition process using the mask assembly MSK provided through the methods shown in FIGS. 5A to 5E.

The electron control layer ECL may be disposed on the light emitting layer EML and the hole control layer HCL. The hole control layer ECL may be commonly disposed in the light emitting part PA and the non-light emitting part NPA. The electron control layer ECL may include an electron transport layer and an electron injection layer. The second electrode CE may be disposed on the electron control layer ECL. The second electrode CE may be commonly disposed in the pixels PX.

A thin film encapsulation layer TFE may be disposed on the light emitting element OLED. The thin film encapsulation layer TFE may be disposed on the second electrode CE to cover the pixel PX. The thin-film encapsulation layer TFE may include at least two inorganic layers and an organic layer between the inorganic layers. The inorganic layers may protect the pixel PX from moisture/oxygen. The organic layer may protect the pixel PX from foreign matters such as dust particles.

The first voltage may be applied to the first electrode AE1 and the second voltage having a lower level than the first voltage may be applied to the second electrode CE through the transistor TR. Holes and electrons injected to the light emitting layer EML may be combined to provide excitons, and the light emitting element OLED may emit light while the excitons are transitioned to the ground state.

FIG. 9 is a drawing for explaining a process of providing the light emitting layer EML shown in FIG. 8.

Referring to FIG. 9, the masks MK of the mask assembly MSK (see FIG. 6) may be disposed on the substrate SUB. The deposition material evaporated in the crucible CR may pass through the deposition openings M-OP defined in the masks MK to be deposited on the substrate SUB. The deposition material DPM deposited on the display opening PX_OP may be provided as the light emitting layer EML.

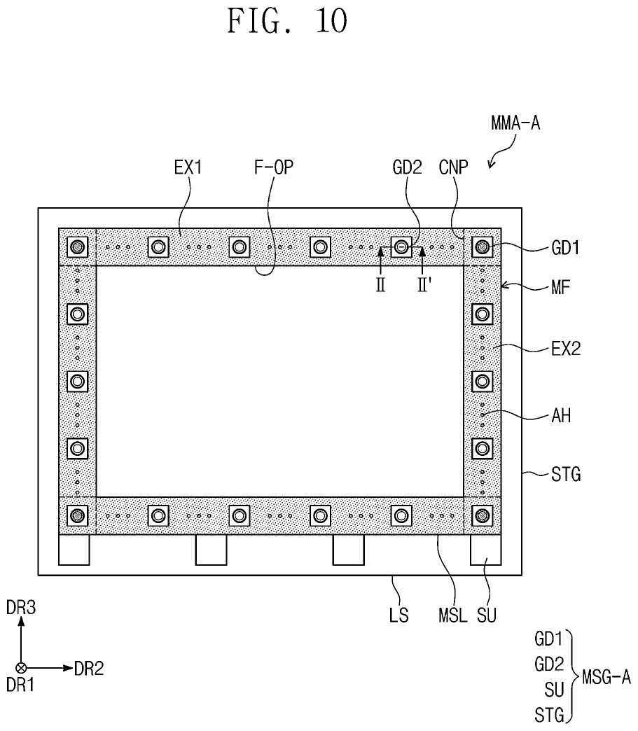

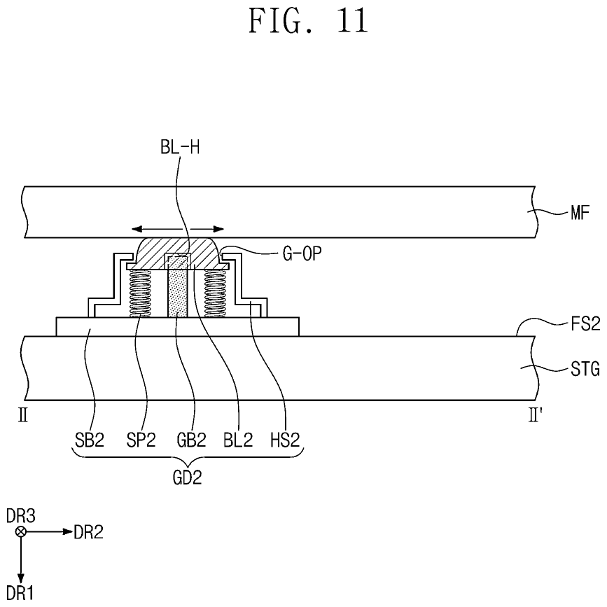

FIG. 10 is a plan view of the mask stage and the mask frame in a state where the front surface of the stage is viewed according to another embodiment of the invention. FIG. 11 is a cross-sectional view cut along II-Il′ shown in FIG. 10. For the same/similar components as FIGS. 1 to 4A, the same/similar reference numerals are used and their repetitive descriptions will be omitted.

FIG. 10 is a plan view illustrating a state viewed from the front surface of the stage STG included in the mask assembly manufacturing device MMA-A according to an embodiment.

Referring to FIG. 10, the mask assembly manufacturing device MMA-A may include the support part SUP (see FIG. 1) and the mask stage MSG-A.

The mask stage MSG-A may include a stage STG, a plurality of support units SU disposed on the stage STG, a plurality of first and second guide units GD1, GD2 disposed on the stage STG.

The mask frame MF may be disposed on the stage STG. The mask frame MF may have a rectangular frame shape. The mask frame MF may include the frame opening F-OP of a rectangular shape. The frame opening F-OP may be provided by penetrating through the rear surface from the front surface of the mask frame MF. As the support units SU support the lower side MLS of the mask frame MF, the mask frame MF may be stably disposed on the stage STG.

The mask frame MF may include the first extension parts EX1 extending in parallel in the second direction DR2 and facing to each other in the third direction DR3, and the second extension parts EX2 extending in parallel in the third direction DR3 and facing to each other in the second direction DR2.

Areas in which the ends of the first extension parts EX1 overlap the ends of the second extension parts EX2 in a plan view are displayed with dotted lines, and portions displayed with bold dotted lines may be defined as the corner parts CNP.

The stage STG, the support units SU, and the first guide units GD1 may correspond to the stage STG, the support units SU, and the guide units GD described with reference to FIGS. 1 to 4A, respectively, and repetitive descriptions will be omitted.

The mask stage MSG-A according to an embodiment may further include second guide units GD2. The second guide units GD2 may overlap the mask frame MF. More specifically, the first guide units GD1 overlap the corner parts CNP of the mask frame MF, and the second guide units GD2 may overlap a portion other than the corner parts CNP in the mask frame MF in a plan view.

The second guide units GD2 may function to support the mask frame MF together with the first guide units GD1. In other words, the first guide units GD1 may support the corner parts CNP of the mask frame MF, and the first and second extension parts EX1, EX2 other than the corner parts CNP may be supported by the second guide units GD2.

When the mask frame MF is seated on the mask fate MSG-A, the components contacting the mask frame MF may be the support units SU, the first guide units GD1 and the second guide units GD2. Accordingly, the mask frame MF may be spaced apart from the stage STG.

According to the embodiment, some of the air holes AH defined in the stage STG may be disposed between the adjacent first guide unit GD1 and second guide unit GD2. The other air holes AH may be disposed between the second adjacent guide units GD2.

The first guide units GD1 may have the configuration corresponding to the guide units GD described with reference to FIG. 4A.

FIG. 11 illustrates the second guide unit GD2 disposed on the second front surface FS2 of the stage STG and the mask frame MF disposed on the second guide unit GD2.

According to an embodiment, the second guide unit GD2 may include a base part SB2, a cover part HS2, a tilting part BL2, a guide part GB2, and an elastic part SP2.

The base part SB2 may be disposed on the stage STG. The base part SB2 may be fastened on the stage STG by fastening units such as screws. The base part SB2 may be a basal layer on which other components of the second guide unit GD2 may be disposed.

The cover part HS2 may be coupled to the base part SB2 to define the appearance of the second guide unit GD2. The cover part HS2 may have a guide opening G-OP defined therein through which a portion of the tilting part BL2 to be described below may be exposed to the outside. The cover part HS2 and the base part SB2 each may include one of plastic and steel.

The tilting part BL2 may be a component configured to contact the mask frame MF2. One portion of the tilting part BL2 may be disposed inside the cover part HS2. The other portion of the tilting part BL2 may protrude from the cover part HS2 to the outside through the opening of the cover part HS. As the one portion of the tilting part BL2 disposed inside the cover part HS2 has a width larger than a width of the guide opening G-OP in a direction parallel to the second front surface FS, the one portion of the tilting part BL2 may prevent the tilting part BL2 from being separated out of the cover part HS. According to an embodiment, the shape of the tilting part BL2 in a plan view may be one of a circular, elliptical, or polygonal shape.

The tilting part BL2 may define a hole BL-H therein. The hole BL-H may be coupled with a portion of the guide part GB2. In the embodiment, the hole BL-H may have a hexahedral shape.

The guide part GB2 may be disposed between the base part SB2 and the tilting part BL2. One portion of the guide part GB may be coupled to the hole BL-H of the tilting part BL2, and the other portion of the guide part GB2 may be fastened to the base part SB2.

According to the embodiment, one portion of the guide part GB2, coupled to the hole BL-H of the tiling part BL2, may have a hexahedral shape corresponding to the shape of the hole BL-H. In addition, the other portion of the guide part GB2 may be a hexagonal column connected thereto.

According to the embodiment, as the hole BL-H of the tilting part BL2 has a hexahedral shape and the tilting part BL2 coupled to the hole BL-H has the hexahedral shape corresponding to the shape of the hole BL-H, the tilting part BL2 may be only tilted in one direction within the cover part HS2. The one direction may be one of the third direction DR3 and the second direction DR2.

The elastic part SP2 may be provided in plurality to be spaced apart from each other with the guide part GB2 interposed therebetween. One end of the elastic part SP2 may be connected to the base part SB2 and the other end of the elastic part SP2 may be connected to the tilting part BL2. The elastic part SP2 may be provided with a spring having certain elasticity. The elastic part SP2 may be contracted when the mask frame MF is seated on the tilting part BL2 and be released when being unseated. Accordingly, even when a plurality of mask frames are seated and unseated in mask assembly manufacturing processes, the tilting part BL2 may be prevented from being sagged toward the base part SB2.

According to the embodiment, when the mask frame STG is seated on the mask stage MSG-A, as the mask frame STG includes the first guide units GD1 supporting the corner parts CNP and the second guide units GD2 supporting portions other than the corner parts CNP, the friction force between the stage STG and the mask frame STG may be reduced and the mask frame STG may be more stably supported.

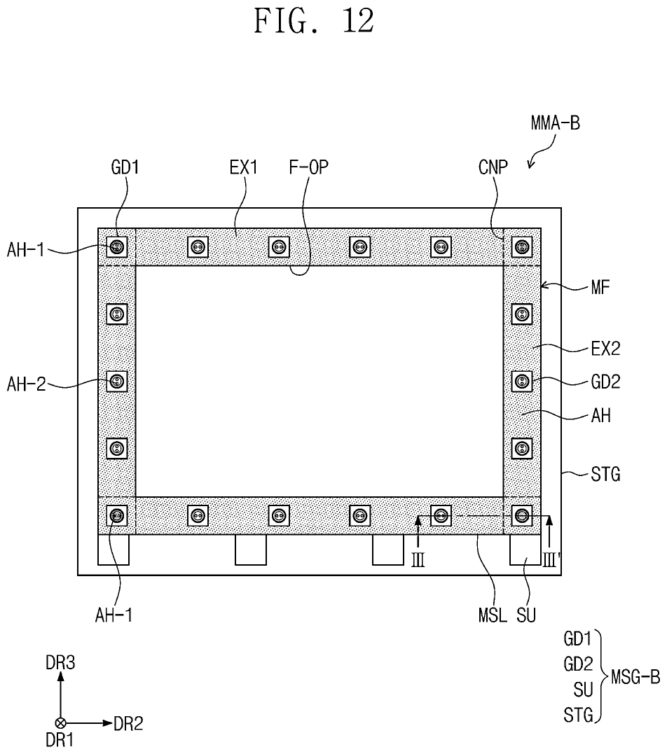

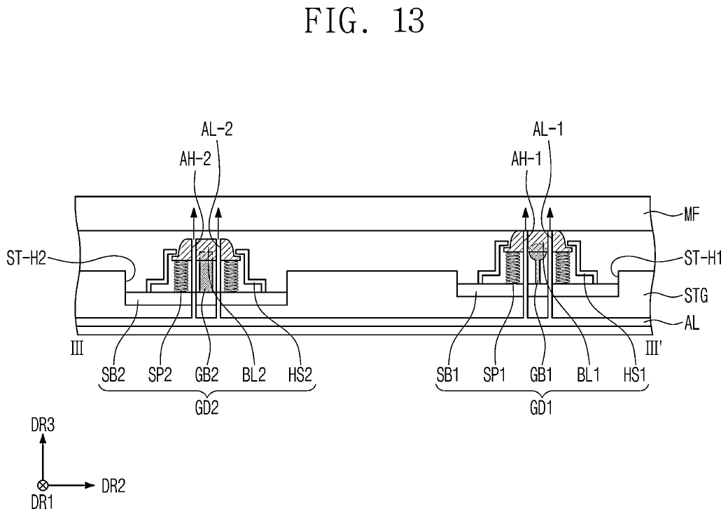

FIG. 12 is a plan view of the mask stage and mask frame in a state where the front surface of the stage is viewed according to still another embodiment of the invention. FIG. 13 is a sectional view cut along III-III′ shown in FIG. 11. For the same/similar components as FIGS. 1 to 4A, 11 and 12, the same/similar reference numerals are used and their repetitive descriptions will be omitted. The differences from the components described with reference to FIG. 10 will be mainly described.

FIG. 12 is a plan view illustrating a state viewed from the front surface of the stage STG included in a mask assembly manufacturing device MMA-B according to an embodiment.

Referring to FIG. 12, the mask assembly manufacturing device MMA-B may include the support part SUP (see FIG. 1) and a mask stage MSG-B.

The mask stage MSG-B may include the stage STG, the plurality of support units SU disposed on the stage STG, the plurality of first and second guide units GD1, GD2 disposed on the stage STG. In the embodiment, the first and second guide units GD1, GD2 may be disposed inside grooves defined in the stage STG.

The air holes AH-1, AH-2 according to the embodiment may overlap the first and second guide units GD1, GD2 in a plan view.

Referring to FIGS. 13, grooves ST-1, ST-2 being partially recessed from the front surface are defined in the stage STG. The first guide unit GD1 and the second guide unit GD2 may be disposed inside the grooves ST-H1, ST-H2 defined in the stage STG. The stage STG may be provided with air lines AL penetrating therethrough.

According to an embodiment, the stage STG may include first connection lines AL-1 connected to the air lines AL and penetrating through the first guide unit GD1, and second connection lines AL-2 connected to the air lines AL and penetrating through the second guide unit GD2.

The first guide unit GD1 may include the base part SB1, the cover part HS1, the tilting part BL1, the guide part GB1, and the elastic part SP1. The second guide unit GD2 may include the base part SB2, the cover part HS2, the tilting part BL2, the guide part GB2, and the elastic part SP2.

The first connection lines AL-1 may penetrate from the base part SB1 through the tilting part BL1 of the first guide part GD1. The air flow provided through the air lines AL may be provided to the mask frame MF overlapping the first guide unit GD1 through the first connection lines Al-1 in a plan view.

The second connection lines AL-2 may penetrate from the base part SB2 through the tilting part BL2 of the second guide part GD2. The air flow provided through the air lines AL may be provided to the mask frame MF overlapping the second guide unit GD2 through the second connection lines Al-1 in a plan view.

According to the embodiment, as the airflow provided from the outside are directly injected to the mask frame MF through the first and second guide units GD1, GD2, the step for finely adjusting the position of the mask frame MF described with reference to FIG. 5C may be more easily performed.

According to the embodiment, when the mask frame MF is disposed on the mask stage MSG-B, the mask frame MF may contact the first guide units GD1 and be spaced apart from the second guide parts GD2. However, the embodiment is not limited thereto, and when the mask frame MF is disposed on the mask stage MSG-B, the mask frame MF may contact all the first and second guide parts GD1, GD2.

According to the invention, when the mask frame is seated on the mask stage, a friction force may be reduced which is generated according to that the stage and the mask frame contact each other. Accordingly, although the mask frame is disposed on the stage that is inclined at a certain angle θ1 with respect to the vertical direction to the plane, the shape of the mask frame may be prevented from becoming deformed due to the friction force caused by the contact between the stage and the mask frame.

Accordingly, the mask assembly manufacturing device may be provided which may increase the yield of the deposition process.

While this invention has been described with reference to exemplary embodiments thereof, it will be clear to those of ordinary skill in the art to which the invention pertains that various changes and modifications may be made to the described embodiments without departing from the spirit and technical area of the invention as defined in the appended claims and their equivalents.

Thus, the scope of the invention shall not be restricted or limited by the foregoing description, but be determined by the broadest permissible interpretation of the following claims.

What is claimed is:

1. A mask assembly manufacturing device comprising:
a support part comprising a first support part comprising a front surface and a rear surface opposing to each other and a second support part inclined at a certain inclination with respect to a direction vertical to the front surface;
a stage disposed on the second support part to correspond to the inclination and on which a mask frame is cradled;
support units disposed at a lower portion of the stage and configured to support the mask frame; and
first guide units configured to be disposed between the stage and the mask frame and overlap corner parts of the mask frame,
wherein each of the first guide units comprises:
a first base part coupled to the stage;
a first cover part connected to the first base part and having a first opening defined therein;
a first tilting part of which one portion is disposed inside the first cover part and another portion protrudes from the first cover part to an outside through the first opening;
a first guide part connected to the first base part and the first tilting part; and
a first elastic part connected to the first base part and the first tilting part.

2. The mask assembly manufacturing device of claim 1, wherein the mask frame contacts a top surface of the first tilting part of each of the first guide units and does not contact a surface of the stage, which faces the mask frame.

3. The mask assembly manufacturing device of claim 2, wherein the first tilting part is tiltable at any direction parallel to a major surface of the stage within the first opening.

4. The mask assembly manufacturing device of claim 1, wherein
the first elastic part is provided with a spring having certain elasticity, and,
when the mask frame contacts a top surface of the first tilting part of each of the first guide units, the first elastic part is contracted.

5. The mask assembly manufacturing device of claim 4, wherein the first elastic part is provided in plurality to be spaced apart from each other and with the first guide part interposed therebetween.

6. The mask assembly manufacturing device of claim 4, wherein the first guide part is surrounded by the first elastic part.

7. The mask assembly manufacturing device of claim 1, wherein, in a plan view, a shape of the first guide part exposed through the first opening is one of circle or rectangle.

8. The mask assembly manufacturing device of claim 1, wherein
the first tilting part defines a first hole having a hemispherical shape therein and a portion of the first guide part is coupled thereto, and
the portion, coupled to the first hole, of the first guide part has a spherical shape.

9. The mask assembly manufacturing device of claim 1, further comprising:
second guide units configured to be disposed between the stage and the mask frame, and overlap the mask frame and spaced apart from the first guide units,
wherein each of the second guide units comprises:
a second base part coupled to the stage;
a second cover part connected to the second base part and having a second opening defined therein;
a second tilting part of which a portion is disposed inside the second cover part and another portion protrudes from the first cover part to an outside through the second opening;
a second guide part connected to the second base part and the second tilting part; and
a second elastic part connected to the second base part and the second tilting part.

10. The mask assembly manufacturing device of claim 9, wherein the mask frame contacts a top surface of the second tilting part of each of the second guide units.

11. The mask assembly manufacturing device of claim 10, wherein the second tilting part is tiltable only in one direction within the second opening.

12. The mask assembly manufacturing device of claim 9, wherein
the second elastic part is provided with a spring having certain elasticity, and,
when the mask frame contacts a top surface of the second tilting part of each of the second guide units, the second elastic part is contracted.

13. The mask assembly manufacturing device of claim 9, wherein
the second tilting part defines a second hole having a hexahedral shape therein and a portion of the second guide part is coupled thereto, and
the portion, coupled to the second hole, of the second guide part has a hexahedral shape.

14. The mask assembly manufacturing device of claim 9, wherein
the first tilting part and the second tilting part comprise stainless steel, or comprise a base part comprising the stainless steel and a coating layer covering the base part, and
the coating layer comprises at least one of a Diamond-like Carbon (DLC) coating layer and a coating layer containing a silicon mixture material.

15. The mask assembly manufacturing device of claim 9, wherein
the stage defines air lines by which an inside of the stage and a top surface of the stage are penetrated, and
an air flow injected through the air lines is provided to a rear surface of the mask frame, which faces the stage.

16. The mask assembly manufacturing device of claim 15, wherein the air lines overlap the mask frame and are disposed between the first guide units and the second guide units.

17. The mask assembly manufacturing device of claim 15, wherein the stage further comprises first connection lines and second connection lines, which are connected to the air lines,
wherein the first connection lines penetrate the first base part and first tilting part, and the second connection lines penetrate the second base part and second tilting part.

18. The mask assembly manufacturing device of claim 17, wherein
the first guide units and the second guide units are disposed into stage grooves defined on the top surface of the stage, respectively, and
the first tilting part contacts the mask frame while the second tilting part is spaced apart from the mask frame.

19. A mask assembly manufacturing method comprising:
seating a mask frame on a stage, wherein the stage is inclined at a certain inclination with respect to a direction vertical to a major surface plane of a support part supporting the stage;
providing an air flow to air lines defined in the stage to adjust a position of the mask frame;
coupling sticks to the mask frame; and
coupling a mask on the sticks,
wherein, in the seating of the mask frame, the mask frame is directly disposed on guide units on the stage and on support units disposed on a lower portion of the stage and is spaced apart from the stage.

20. The mask assembly manufacturing method of claim 19, wherein the guide units overlap corner parts of the mask frame, and
each of the guide units comprises:
a base part coupled to the stage;
a cover part connected to the base part and having an opening defined therein;
a tilting part of which a portion is disposed inside the cover part and another portion overlaps the opening to protrude outside;
a guide part connected to the base part and the tiling part; and
an elastic part connected to the base part and the tiling part,
wherein the tilting part is tiltable at any direction parallel to a major surface of the stage in a state of contacting the mask frame.
